(19) United States
(12) Patent Application Publication
(10) Pub. No.: US 2025/0100250 A1
(43) Pub. Date: Mar. 27, 2025

(54) TRANSPARENT SUBSTRATE PROVIDED WITH A FUNCTIONAL STACK OF THIN LAYERS

(71) Applicant: SAINT-GOBAIN GLASS FRANCE, COURBEVOIE (FR)

(72) Inventors: Denis GUIMARD, AUBERVILLIERS (FR); Anne LELARGE, AUBERVILLIERS (FR)

(21) Appl. No.: 18/729,759

(22) PCT Filed: Jan. 25, 2023
(86) PCT No.: PCT/EP2023/051830

§ 371 Date: Jul. 17, 2024

(30) Foreign Application Priority Data
Jan. 27, 2022 (FR) FR2200706
Apr. 28, 2022 (FR) FR2203983
Jan. 5, 2023 (WO) PCT/EP2023/050188

(51) Int. Cl. B32B 17/10; C23C 14/08; C23C 14/35

(52) U.S. Cl. CPC B32B 17/10036; B32B 17/10174; C23C 14/083; C23C 14/35; B32B 2250/03; B32B 2255/205; B32B 2307/418; B32B 2307/7376; B32B 2315/08

(57) ABSTRACT

A transparent substrate provided on one of its main surfaces with a stack of thin layers, the stack of layers including the following layers starting from the substrate a first dielectric module of one or more thin layers; a tungsten oxide absorbing layer; a second dielectric module of one or more thin layers; wherein the tungsten oxide includes at least one doping element selected from chemical elements of group 1 according to IUPAC nomenclature.

### TECHNICAL FIELD

The invention to a transparent substrate provided with a stack of thin layers conferring “solar control” properties.

### TECHNICAL BACKGROUND

Functional stacks of thin layers are commonly used to provide functions of thermal insulation and/or solar protection to glazings equipping buildings. They aim in particular to reduce the air-conditioning effort and/or to reduce excessive overheating (so-called “solar control” glazings) and/or to reduce the amount of energy dissipated to the outside (so-called “low-emission” glazings).

Solar control functions are desired for the glazings capable of being exposed to high sunshine levels. The capacity of a glazing to limit the amount of light energy transmitted is defined by the solar factor, g, which is the ratio of the total energy transmitted through the glazed surface or the interior glazing to the incident solar energy. The lower the solar factor, g value, the better the protection against solar radiation.

It is common to use “solar control” glazings provided with a stack of thin layers devoid of functional metal layers when radio frequency transparency properties are desired. Instead of functional metal layers, functional layers that absorb infrared radiation are generally used. They may be based on oxides and/or nitrides.

JP 2010180449 A [SUMITOMO METAL MINING CO [JP]] Aug. 19, 2010 discloses a layer based on tungsten oxide deposited by sputtering using a tungsten oxide target comprising chemical elements selected from hydrogen, alkali metals, alkaline earth metals and rare earth metals. The layer has a “solar control” function by virtue of its high absorption of near-infrared radiation.

EP 3686312 A1 [SUMITOMO METAL MINING CO [JP]] Jul. 29, 2020 describes a layer based on tungsten oxide doped with cesium, and a method for depositing such a layer by sputtering. The layer has a transparency to radio waves and a “solar control” function by virtue, in particular, of its high absorption of infrared radiation.

### SUMMARY OF THE INVENTION

### Technical Problem

A functional stack is described as a functional stack suitable for building applications when it meets a double requirement: high light transmission and a low solar factor value. A functional stack is therefore suitable when it has a selectivity value, s, defined as the ratio of the light transmission to the high solar factor. A high selectivity is in particular above 1.2 for monolithic glazings having a light transmission of about 70%, or at least 1.3 for laminated glazings having a light transmission of about 70%.

Additionally, it is preferable for a functional stack to have a certain chemical and mechanical durability for certain applications, in particular in single glazings, when it is directly exposed to the external or internal environment of a building.

There also remains a need to improve the energy performance of the stacks of thin layers that do not comprise any functional metal layers reflecting infrared radiation, in particular that do not comprise silver-based functional metal layers.

Radio frequency transparency may further be desired.

### Solution to the Technical Problem

A first aspect of the invention relates to a transparent substrate as disclosed in claim 1, the dependent claims being advantageous embodiments.

The transparent substrate according to the invention is provided on one of its main surfaces with a stack of thin layers, said stack of layers consisting of the following layers starting from the substrate:
a first dielectric module of several thin layers;
an absorbent tungsten oxide layer;
a second dielectric module of one or more thin layers;
wherein the tungsten oxide comprises at least one doping element selected from the chemical elements of group 1 according to the IUPAC nomenclature.

Preferably, said stack comprises no metal layer.

Several thin layers in said second dielectric module can make it possible to modulate the optical characteristics of the stack.

Said second dielectric module preferably comprises at least one succession of two layers (that is to say two layers, one after the other) with a low-index layer (that is to say which is made of a material with a low refractive index) having a refractive index at 550 nm of between 1.50 and less than 1.90 and a high-index layer (that is to say which is made of a material with a high refractive index) having a refractive index at 550 nm of between more than 2.10 and 2.70. In general, a layer of average index (that is to say which is made of a material with an average refractive index) has a refractive index at 550 nm of between 1.90 and 2.10, including these two values. The refractive index of a material is generally evaluated to the nearest hundredth.

Thus, one, or even several, succession(s) of two layers, one of which has a low index and the other of which has a high index, in the second dielectric module can make it possible to achieve high selectivity while maintaining the benefits of transparency to electromagnetic waves used in telecommunications and the absence of a metal layer. This advantage is more significant when, for a succession of two layers, or even for each succession of two layers, said low-index layer is preferably closer to said absorbent tungsten oxide layer than to said high-index layer.

Thus, one, or even several, succession(s) of two layers, one of which has a low index and the other of which has a high index, in the second dielectric module can make it possible to obtain a high stability of the color in reflection based on the observation angle. This advantage is more significant when, for a succession of two layers, or even for each succession of two layers, said low-index layer is preferably closer to said absorbent tungsten oxide layer than to said high-index layer.

Preferably, the difference in index between two layers following one another in a succession of two layers, and more preferably in each succession of two layers, is at least 0.4, and preferably at least 0.5, or even at least 0.7; thus, the effect of the succession is more significant.

Said second dielectric module preferably comprises two successions of two layers, or even three successions of two layers, with, for each succession, a low-index layer and a high-index layer, said successions preferably each being with said low-index layer of the succession closer to said absorbent tungsten oxide layer than said high-index layer of the succession.

Said low-index layer is preferably chosen from a material based on silicon dioxide SiO₂, and said high-index layer is preferably chosen from a material based on zirconium silicon nitride-zirconium SiₓN_{y}Zr_{z}, or titanium dioxide TiO₂.

Other advantageous embodiments are presented in the detailed description.

A second aspect of the invention relates to a glazing comprising a transparent substrate according to the first aspect of the invention.

A third aspect of the invention relates to a method for manufacturing a transparent substrate according to the first aspect of the invention.

### Advantages of the Invention

A notable advantage of a glazing comprising a transparent substrate according to the invention is a gain of up to more than 10% on the selectivity while maintaining a sufficient light transmission level, greater than 65% in single glazing applications, and a thermal transmission factor, Ug, of 5 W/m²·K, or even less.

Another advantage of the invention is that the functional stack has better mechanical and chemical durability, as well as preservation of its optical and energy performance after heat treatment, in particular by the encapsulation of the tungsten oxide layer by nitride-based layers, as detailed in some embodiments.

The exterior and interior reflections may further be very low; they may be less than 12%.

### BRIEF DESCRIPTION OF THE DRAWINGS

FIG. 1 is a schematic depiction of a first embodiment of the first aspect of the invention.

FIG. 2 is a schematic depiction of a first embodiment of a double glazing according to the second aspect of the invention.

FIG. 3 is a schematic depiction of a second embodiment of a double glazing according to the second aspect of the invention.

FIG. 4 is a schematic depiction of a laminated glazing according to the second aspect of the invention.

FIG. 5 is a schematic depiction of embodiments of transparent substrates provided with a stack.

### DETAILED DESCRIPTION OF EMBODIMENTS

The following definitions and conventions are used.

The term “above”, respectively “below”, describing the position of a layer or of an assembly of layers and defined in relation to the position of another layer or another assembly, means that said layer or said assembly of layers is closer to, respectively further from, the substrate.

These two terms, “above” and “below”, do not at all mean that the layer or the assembly of layers which they describe and the other layer or the other assembly with respect to which they are defined are in contact. They do not exclude the presence of other intermediate layers between these two layers. The expression “in contact” is explicitly used to indicate that no other layer is positioned between them.

Without any fuller information or qualifier, the term “thickness” used for a layer corresponds to the physical, real or geometric thickness, e, of said layer. It is expressed in nanometers.

The expression “dielectric module” denotes one or more layers in contact with one another forming an assembly of layers which is dielectric overall, that is to say that it does not have the functions of a functional metal layer. If the dielectric module comprises several layers, they may themselves be dielectric. The physical, real or geometric thickness, of a dielectric module of layers, corresponds to the sum of the physical, real or geometric thicknesses, of each of the layers which constitute it.

In the present description, the expressions “a layer of” or “a layer based on”, used to describe a material or a layer as to what it contains, are used equivalently. They mean that the mass fraction of the constituent that it comprises is at least 50%, in particular at least 70%, preferably at least 90%. In particular, the presence of minority or doping elements is not excluded.

The term “transparent” used to describe a substrate means that the substrate is preferably colorless, non-opaque and non-translucent in order to minimize the absorption of the light and thus retain a maximum light transmission in the visible electromagnetic spectrum.

“Light transmittance” is understood to mean the light transmittance, denoted TL, as defined and measured in section 4.2 of the standard EN 410.

The light transmission in the visible spectrum, TL, the solar factor, g, and the selectivity, s, the internal reflection, Rint, and the external reflection, Rext, in the visible spectrum are defined, measured and calculated in conformity with the standards EN 410, ISO 9050 and ISO 10292.

In the case of a laminated glazing, “thermal transmission factor,” Ug, is understood to mean the thermal transmission factor as defined according to standards EN 673.

In accordance with the nomenclature of IUPAC, group 1 of the chemical elements comprises hydrogen and alkaline elements, that is, lithium, sodium, potassium, rubidium, cesium and francium.

The expressions “optical refraction index” and “optical extinction coefficient”, are understood as the optical refraction index, n, and optical extinction coefficient, k, as defined in the technical field, in particular according to the Forouhi & Bloomer described in the Forouhi & Bloomer, Handbook of Optical Constants of Solids II, Palik, E. D. (ed.), Academic Press, 1991, Chapter 7.

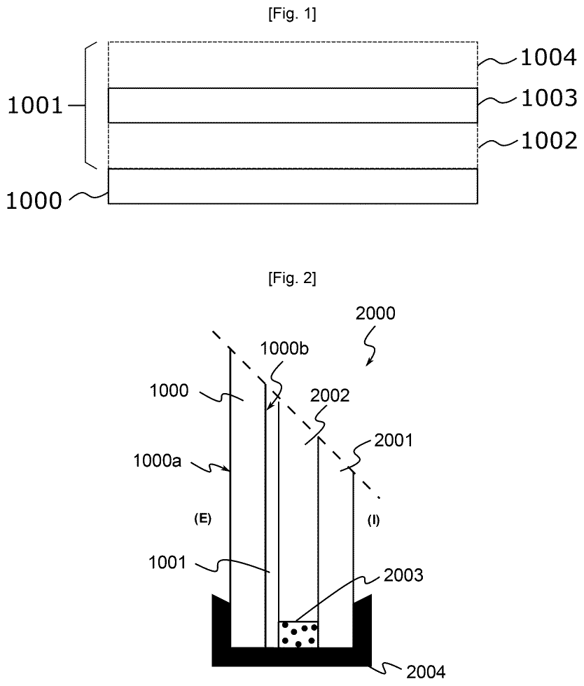

According to a first aspect of the invention, with reference to FIG. 1, a transparent substrate 1000 is provided, which is provided on one of its main surfaces with a stack 1001 of thin layers, said stack 1001 of layers consists of the following layers starting from the substrate 1000:
a first dielectric module 1002 of one or more thin layers;
an absorbent tungsten oxide layer 1003;
a second dielectric module 1004 of several thin layers;

The tungsten oxide comprises at least one doping element selected from the chemical elements of group 1 according to the IUPAC nomenclature.

The absorbent tungsten oxide layer 1003 is a layer that absorbs infrared radiation, preferably that absorbs infrared radiation whose wavelength is greater than 780 nm.

Surprisingly, an absorbent tungsten oxide layer 1003 comprising a doping element chosen from the elements of group 1 according to the IUPAC nomenclature encapsulated between two dielectric modules makes it possible to increase the selectivity.

The stack 1001 of the transparent substrate 1000 according to the first aspect of the invention does not comprise any functional metal layers.

According to certain particular embodiments, the absorbent tungsten oxide layer 1003 may comprise the doping element X or the doping elements X1, X2, . . . in proportions such that the molar ratio, X/W of said element on tungsten, W, or the sum of the molar ratios of each element on tungsten (X1+X2+ . . . )/W is between 0.01 and 1, preferably between 0.01 and 0.6, or even between 0.02 and 0.3.

It has been observed that these molar ratio values can make it possible to obtain optimal selectivity values while making it possible to limit the amount of doping elements used, and therefore to generate savings on the use of the mineral resources for the doping elements, as well as a reduction in manufacturing costs.

According to certain embodiments, the absorbent tungsten oxide layer 1003 may comprise at least one doping element selected from hydrogen, lithium, sodium, potassium and cesium.

Among the elements of group 1, these particular elements can make it possible to obtain advantageous selectivity values, that is to say higher values.

According to particularly preferred embodiments, the absorbent tungsten oxide layer 1003 may comprise cesium as a doping element, and the molar ratio of cesium to tungsten is between 0.01 and 1, preferably between 0.05 and 0.4. These embodiments make it possible to obtain the best performance as to the increase in selectivity, the preservation of colors, and the cost savings.

According to certain embodiments, the thickness of the absorbent tungsten oxide layer 1003 may be between 6 and 450 nm, preferably between 20 and 250 nm, or even between 40 and 200 nm.

The transparent substrate 1000 may preferably be planar. It may be organic or inorganic, rigid or flexible. In particular, it may be a mineral glass, for example a soda-lime-silica glass.

Examples of organic substrates which can advantageously be used in the implementation of the invention may be polymer materials, such as polyethylenes, polyesters, polyacrylates, polycarbonates, polyurethanes or polyamides. These polymers can be fluoropolymers.

Examples of inorganic substrates which can advantageously be employed in the invention may be sheets of inorganic glass or glass-ceramic. The glass may preferably be a glass of soda-lime-silica, borosilicate, aluminosilicate or else alumino-borosilicate type. According to a preferred embodiment of the invention, the transparent substrate 1000 is a sheet of soda-lime-silica mineral glass.

According to certain embodiments, the first dielectric module 1002 and/or the second dielectric module 1004 may comprise one or more layers based on nitride and/or oxide, preferably based on zinc tin oxide, zinc oxide, titanium oxide, zirconium oxide, aluminum nitride, silicon zirconium nitride or silicon nitride optionally doped with aluminum, zirconium and/or boron.

According to advantageous embodiments, the first dielectric module 1002 and/or the second dielectric module 1004 consist of one or more nitride-based layers. According to examples of embodiments, the nitride-based layer(s) of the first dielectric module 1002 and/or the second dielectric module 1004 are chosen from aluminum nitride, silicon nitride, titanium nitride, niobium nitride, silicon zirconium nitride, silicon nitride doped with aluminum, zirconium and/or boron.

When the layer(s) of the first dielectric module 1002 and of the second dielectric mode 1004 are nitride-based, they make it possible to encapsulate the absorbent layer based on tungsten oxide.

This encapsulation allows a double protection of the absorbent layer 1003 based on tungsten oxide. On the one hand, it prevents any contamination by elements capable of diffusing into the stack 1001 from the substrate 1000, such as in particular alkali metal ions or oxygen in the case of a heavy mineral glass substrate. On the other hand, it makes it possible to limit, in particular during a heat treatment step of the annealing type, the diffusion of oxygen into the stack 1001 toward the absorbent layer 1003 based on tungsten oxide from the atmosphere and/or the substrate.

By virtue of the encapsulation, the chemical composition and the degree of oxidation of the absorbent tungsten oxide layer 1003 vary little over time, or if they vary, this variation is favorable for the selectivity. Moreover, when the stack is subjected to an annealing heat treatment, the encapsulation ensures a proper level of selectivity. In use, the substrate 1000 according to the first aspect of the invention is more durable, in particular its performance is preserved over the long term.

A second aspect of the invention relates to a glazing, in particular a single, double or triple glazing, and a laminated glazing, comprising a transparent substrate according to the first aspect of the invention.

According to a second aspect of the invention, a single or double glazing is provided comprising a substrate according to the first aspect of the invention.

A single glazing, or monolithic glazing, comprises a single substrate, in particular a mineral glass sheet. When the substrate according to the invention is used as monolithic glazing, the functional stack of this layers is preferably deposited on the face of the substrate directed toward the interior of the room of the building on the walls of which the glazing is installed. In such a configuration, it can be advantageous to protect the first layer and optionally the stack of thin layers from physical or chemical damage using an appropriate means.

A multiple glazing comprises at least two substrates, in particular mineral glass sheets, that are parallel and separated by an insulating gas-filled cavity. The majority of multiple glazings are double or triple glazings, that is to say that they respectively comprise two or three glazings. When the substrate according to the invention is used as element of a multiple glazing, the functional stack of thin layers is preferably deposited on the face of the glass sheet directed inward in contact with the insulating gas. This arrangement has the advantage of protecting the stack from chemical or physical damage from the external environment.

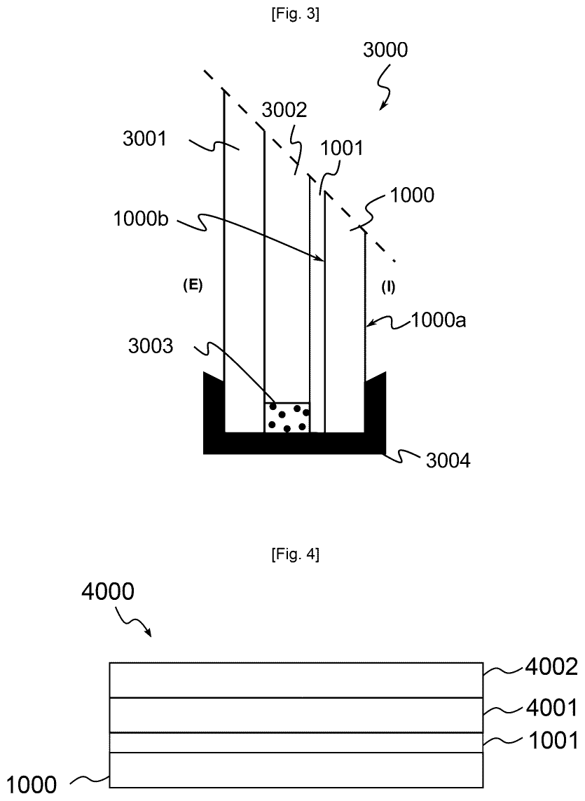

According to preferred embodiments, with reference to FIG. 2 and FIG. 3, the glazing is a double glazing 2000, 3000 comprising a transparent substrate 1000 according to any one of the above-disclosed embodiments so that the functional stack 1001 of layers is located facing two and/or three of said glazing 9000, 10000. In the figure, (E) corresponds to the exterior of the premises where the glazing is installed, and (I) to the interior of the premises.

According to a first embodiment, with reference to FIG. 2, the glazing 2000 comprises a first transparent glass sheet 1000 with an inner surface 1000a and an outer surface 1000b, a second glass sheet 2001 with an inner surface and an outer surface, an insulating gas-filled cavity 2002, a spacer 2003 and a seal 2004.

The glass sheet 1000 comprises, on and in contact with its inner surface 1000b in contact with the gas of the insulating gas-filled cavity 9002, a functional stack 1001 according to the first aspect of the invention. The functional assembly 1001 is preferably deposited so that its outer surface, which is opposite the surface 1000b of the transparent glass sheet 1000, is directed toward the interior (I) of the premises, for example a building, wherein the glazing is used. In other words, the functional stack 1001 is arranged on face 2 of the glazing starting from the exterior (E).

According to another embodiment, with reference to FIG. 3, the glazing is a double glazing 3000 comprising a first glass sheet 1000 with an inner surface 1000a and an outer surface 1001b, a second transparent glass sheet 3001 with an inner surface and an outer surface, an insulating gas-filled cavity 3004, a spacer 3003 and a seal 3004.

The glass sheet 1000 comprises, on its inner surface 1000a in contact with the gas of the insulating gas-filled cavity 9004, a functional stack 1001 according to the first aspect of the invention. The functional assembly 1001 is preferably arranged so that its outer surface that is opposite the surface 1000a of the transparent glass sheet 1000 is directed toward the exterior (E) of the premises. In other words, the functional stack (1001) is arranged on face 3 of the glazing starting from the exterior (E).

Referring to FIG. 4, also provided is a laminated glazing 4000 comprising a first transparent substrate 1000 according to the first aspect of the invention, a lamination interlayer 4001 and a second transparent substrate 4002, such that the first transparent substrate 1000 and the second transparent substrate 4002 are in adhesive contact with the lamination interlayer 4001 and the stack 1001 of thin layers of the first transparent substrate 1000 is in contact with the lamination interlayer 4001.

The lamination interlayer 4001 may consist of one or more layers of thermoplastic material. Examples of thermoplastic material are polyurethane, polycarbonate, polyvinyl butyral (PVB), polymethyl methacrylate (PMMA), ethylene vinyl acetate (EA) or an ionomer resin.

The lamination interlayer 4001 may be in the form of a multilayer film. It may also have particular functionalities such as, for example, acoustic or anti-UV properties.

Typically, the lamination interlayer 4001 comprises at least one PVB layer. Its thickness is between 50 μm and 4 mm. In general, it is less than 1 mm.

The methods for depositing thin layers on substrates, in particular glass substrates, are methods well known in industry. By way of example, the deposition of a stack of thin layers on a glass substrate is carried out by successive depositions of each thin layer of said stack by passing the glass substrate through a succession of deposition cells suitable for depositing a given thin layer.

The deposition cells can use deposition methods such as magnetic field assisted sputtering, ion beam assisted deposition (IBAD), evaporation, chemical vapor deposition (CVD), plasma enhanced chemical vapor deposition (PECVD), low pressure chemical vapor deposition (LPCVD), etc.

The magnetic field enhanced sputtering deposition method is particularly used. The conditions for deposition of layers are widely documented in the literature, for example in patent applications WO2012/093238 A1 and WO2017/00602 A1.

According to a third aspect of the invention, a method is provided for manufacturing a transparent substrate according to the first aspect of the invention, such that the absorbent tungsten oxide layer is deposited by a magnetron sputtering method using a tungsten oxide target doped using a chemical element chosen from the chemical elements of group 1 according to the IUPAC nomenclature.

The tungsten oxide target may in particular contain one or more doping elements in the proportions as described for the tungsten oxide layer doped in some embodiments of the first aspect of the invention.

The absorbent tungsten oxide layer can be deposited by sputtering using the aforementioned target under a deposition atmosphere composed of 60% to 100% argon and 0% to 40% dioxygen, preferably 70% to 85% argon and 15% to 30% dioxygen.

The absorbent tungsten oxide layer may be deposited under a pressure between 1 to 15 mTorr, preferably 3 to 10 m Torr.

Preferably, the deposition can be carried out cold, that is to say at a temperature of less than 100° C., in particular between 20° C. and 60° C., for the substrate.

The deposition can also be carried out hot, in particular at a temperature between 100° C. and 400° C.

According to particular embodiments, the substrate 1000, after deposition of the stack 1001, can undergo an annealing heat treatment. The annealing temperature may be between 450° C. and 800° C., in particular between 550° C. and 750° C., or even between 600° C. and 700° C. The annealing time may be between 5 min and 30 min, in particular between 5 min and 20 min, or even between 5 min and 10 min.

All the embodiments described, whether they relate to the first aspect or the second aspect of the invention, can be combined with one another without modification or particular adaptation. In the event that technical incompatibilities appear during the implementation of one of these combinations, it is within the scope of the person skilled in the art to be able to solve them by means of their knowledge without this requiring undue effort, in particular by implementing a research program.

### EXAMPLES

The features and advantages of the present invention are shown by the non-limiting examples disclosed hereinafter.

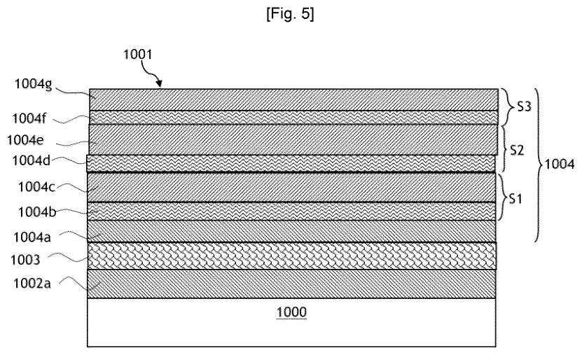

Tables 2, 4 and 6 indicate the composition and the thickness expressed in nanometers of the various layers. The numbers in the first two columns correspond to the references of FIG. 5.

The layer, denoted CWO, of cesium-doped tungsten oxide. The molar ratio of cesium to tungsten in the layer is about 0.05-0.06.

The stacks of thin layers of the examples and of the counter-examples were deposited by magnetic-field-assisted cathode sputtering (magnetron method) whose characteristics are widely documented in the literature, for example in patent applications WO2012/093238 and WO2017/00602. The substrate 1000 is a soda-lime-silica mineral glass 6 mm or 4 mm thick. After deposition and before the optical measurements, the 6 mm substrates were subjected to a heat treatment at 650° C. for 10 min under air.

The nature of the targets used and the deposition conditions of the examples and the counter-examples are grouped in table 1.

TABLE 1

| | | Pressure | Ar | O2 | N2 | Power |
|---|---|---|---|---|---|---|
| | Target | (μbar) | (sccm) | (sccm) | (sccm) | (W) |
| Si₃N₄ | Si:Al | 5 | 7 | 0 | 14 | 2000 |
| SiZr27N | Si:Zr | 2 | 15 | 0 | 15 | 1000 |
| | 27 at. % | | | | | |
| SiO₂ | Si:Zr | 2 | 15 | 0 | 18 | 1000 |
| | 17 at. % | | | | | |
| NbN | Nb | 2 | 40 | 0 | 10 | 500 |
| TiN | Ti | 2 | 32 | 0 | 15 | 2500 |
| NiCr | NiCr:Cr | 2 | 20 | 0 | 0 | 500 |
| | 20 wt. % | | | | | |
| CWO | CWO:Cs/W | 4-10 | 30-40 | 2-10 | 0 | 1300 |
| | 0.3-0.4 | | | | | |

Silicon nitride, Si₃N₄, layers are deposited using a Si: Al 8 wt % target at 5 μbar under an atmosphere devoid of dioxygen and under flow of nitrogen at 14 sccm; generally, the layers based on zinc oxide, ZnO, or tin dioxide, SnO₂, or silicon nitride, Si₃N₄, are layers of average index.

Silicon dioxide, SiO₂, layers are layers of low refractive index; it is 1.53 at the wavelength of 550 nm. They are deposited using a Si: Al 8 wt % target at 4 μbar under an atmosphere devoid of nitrogen and under a flow of dioxygen at 10 sccm.

The layers of silicon-zirconium nitride, SiZr27N, are layers of high refractive index; it is 2.40 at the wavelength of 550 nm. They are deposited using a 27 wt % (by weight) target on the total Si+Zr, at 5 μbar under an atmosphere devoid of dioxygen and under a flow of nitrogen at 15 sccm.

The solar factor, g, the selectivity, s, the light transmission, TL, the light reflection on the interior face, Rint, and on the exterior face, Rext, as well as the color in transmission, on the interior face and on the exterior face, were measured for each substrate of examples E1a, E1b, E3 and of counter-examples CE1a, CE1b, CE3A, CE3b and CE3c assembled in a single glazing, the stack being on the interior face, called “face 2.”

The expression “color”, used to describe a transparent substrate provided with a stack, is understood to mean the color as defined in the L*a*b* CIE 1976 chromatic space according to standard ISO 11664, in particular with a D65 illuminant and a visual field of 2° or 10° for the reference observer. It is measured in accordance with said standard.

The light transmission in the visible spectrum, TL, the solar factor, g, and the selectivity, s, and the internal reflection, Rint, and the external reflection, Rext, in the visible spectrum are defined, measured and calculated in conformity with the standards EN 410, ISO 9050 and/or ISO 10292.

The thermal transmission factor, Ug, is defined, measured and calculated in accordance with standard EN 673.

Two first counterexamples CE1a and CE1b of a substrate according to the first aspect of the invention and two examples E1a and E1b according to the invention are disclosed in table 2, which indicates the composition and the thickness expressed in nanometers of the various layers.

In counterexamples CE1a and CE1b and the two examples E1a and E1b, the transparent substrate is a soda-lime-silica glass with a thickness of 6 mm marketed under the trade name Planiclear®.

TABLE 2

| | | | CE1a | CE1b | E1a | E1b |
|---|---|---|---|---|---|---|
| 1004g | S3 | SiZr27N | — | — | — | 3 |
| 1004f | | SiO₂ | — | — | — | 49 |
| 1004e | S2 | SiZr27N | — | — | 11 | 64 |
| 1004d | | SiO₂ | — | — | 37 | 26 |
| 1004c | S1 | SiZr27N | — | | 60 | 14 |
| 1004b | | SiO₂ | — | | 40 | 98 |
| 1004a | | Si₃N₄ | | 23 | 66 | 5 |
| 1003 | | CWO | | 33 | 45 | 50 |
| 1002c | | Si₃N₄ | 10 | 34 | 19 | 5 |
| 1002b | | NbN | 0.8 | 0.8 | 0.3 | 0.5 |
| 1002a | | Si₃N₄ | 59 | 5 | 30 | 62 |
| 1000 | | glass | 6 mm | 6 mm | 6 mm | 6 mm |

All of the properties of these examples and counter-example are disclosed in Table 3.

The light transmission, TL, the “direct solar transmittance,” TE, the “solar factor,” TTS (or T_{TS}) and the selectivity, SEL, were measured and/or calculated according to ISO 13837:2021 for each example and counter-example.

For each example and counter-example, the colorimetric parameters a* and b* were measured and/or calculated in transmission (a*T, b*T) and in external reflection (a*Rext, b*Rext) in the L*a*b* CIE 1976 chromatic space according to standard ISO 11664-4:2019 with a D65 illuminant and a visual field of 2° or 10° for the reference observer. Characteristic a* is the chromatic position on a green-red axis (between −500 and 500), and b* is the chromatic position on a blue-yellow axis (between −200 and 200).

TABLE 3

| | CE1a | CE1b | E1a | E1b |
|---|---|---|---|---|
| TL | 68.7 | 70.0 | 69.1 | 69.0 |
| TE | 66.8 | 55.6 | 46.7 | 42.6 |
| TST | 70.8 | 63.7 | 56.3 | 53.6 |
| SEL | 0.97 | 1.10 | 1.23 | 1.29 |
| a*T | −.09 | −4.3 | −4.9 | −4.9 |
| b*T | −1.0 | −3.1 | 1.5 | 0.8 |
| Rext | 20.7 | 12.0 | 11.7 | 7.2 |
| a*Rext | −2.2 | −1.8 | −2.2 | −2.7 |
| b*Rext | 2.6 | 3.3 | −0.4 | −2.8 |
| Rint | 25.7 | 11.9 | 10.1 | 5.5 |
| a*Rint | −2.2 | −1.8 | −2.2 | −2.7 |
| b*Rint | 2.6 | 3.3 | −0.4 | −2.8 |
| a*Rext30° | −2.6 | −3.0 | −0.5 | −3.0 |
| b*Rext30° | 1.5 | 1.9 | 0.4 | −0.5 |
| a*Rext45° | −2.8 | −4.0 | 1.0 | 0.9 |
| b*Rext45° | 0.4 | 0.3 | 1.9 | 1.7 |
| a*Rext60° | −2.4 | −4.2 | 0.0 | 2.9 |
| b*Rext60° | −0.4 | −1.3 | 2.6 | 2.9 |

Table 3 shows that the two examples E1a and E1b according to the invention have a light transmission TL similar to that of counterexamples CE1a and CE1b and an energy transmission, TE, that is better (lower) than that of counterexamples CE1a and CE1b.

Table 3 shows that the two examples E1a and E1b according to the invention allow a solar factor TTS gain (decrease), compared to counterexamples CE1a and CE1b. This gain illustrates the synergistic effect of the combination of the tungsten oxide-based absorbent layer with the two adjacent dielectric modules and with the second module which comprises one, two or three succession(s).

The selectivity obtained is high; it is greater than 1.2 in a monolithic glazing configuration and for a light transmittance of about 70%.

The exterior and interior reflections are further very low; they are less than 12%.

The last six rows of Table 3 show the stability of the color according to a* and b*, in external reflection, at 30°, 45° and 60° relative to the a* and b* values at 0° of the eighth and ninth rows.

A second series of two counterexamples CE2a and CE2b of a substrate according to the first aspect of the invention and two examples E2a and E2b according to the invention are disclosed in table 4, which indicates the composition and the thickness expressed in nanometers of the various layers.

TABLE 4

| | | | CE2a | CE2b | E2a | E2b |
|---|---|---|---|---|---|---|
| 1004e | S2 | SiZr27N | — | — | 10 | 8 |
| 1004d | | SiO₂ | — | — | 33 | 204 |
| 1004c | S1 | SiZr27N | — | — | 77 | 88 |
| 1004b | | SiO₂ | — | — | 152 | 139 |
| 1004a | | Si₃N₄ | — | 55 | 5 | 5 |
| 1003 | | CWO | — | 58 | 61 | 61 |
| 1002c | | Si₃N₄ | 65 | — | — | — |
| 1002b | | NbN | 2.6 | — | — | — |
| 1002a | | Si₃N₄ | 5 | 31 | 39 | 48 |
| 1000 | | glass | 4 mm | 4 mm | 4 mm | 4 mm |

The absorbent tungsten oxide (CWO) layer and the silicon nitride, Si₃N₄, silicon dioxide, SiO₂, and silicon-zirconium nitride, SiZr27N, layers are deposited like for the examples and counterexamples of the first series of examples of Tables 2 and 3.

Two laminated glazing counterexamples CEV2a and CEV2b were made from, respectively, the substrates of counterexamples CE2a and CE2b; two laminated glazing examples EV2a and EV2b according to the second aspect of the invention were made from, respectively, the substrates of examples E2a and E2b.

For each of counterexamples CEV2a, CEV2b, and for each of examples EV2a and EV2b, the lamination interlayer 4001 is a PVB insert 0.76 mm thick. The second substrate 4002 of counterexamples CEV2a, CEV2b, and examples EV2a and EV2b is a soda-lime-silica mineral glass with a thickness of 4 mm marketed under the trade name Planiclear®. For these examples EV2a and EV2b of laminated glazings comprising a stack and these counterexamples CEV2a, CEV2b of laminated glazings comprising a stack, the stack is positioned on face 3.

Like for the first series of examples of Tables 2 and 3, all of the properties of these examples and counterexamples are disclosed in Table 5.

TABLE 5

| | CEV2a | CEV2b | EV2a | EV2b |
|---|---|---|---|---|
| TL | 68.6 | 69.0 | 69.0 | 69.0 |
| TE | 59.6 | 48.4 | 42.4 | 41.1 |
| TST | 65.6 | 57.2 | 52.9 | 51.8 |
| SEL | 1.05 | 1.21 | 1.3 | 1.33 |
| a*T | −1.6 | −5.1 | −5.0 | −5.0 |
| b*T | −0.2 | −5.3 | −2.7 | −2.9 |
| Rext | 17.4 | 8.9 | 9.9 | 9.7 |
| a*Rext | −1.5 | 0.0 | −2.8 | −3.0 |
| b*Rext | 3.0 | −4.8 | 0.4 | 1.7 |
| Rint | 9.7 | 9.6 | −.1 | 8.5 |
| a*Rint | −0.5 | −5.9 | −5.5 | −3.5 |
| b*Rint | 2.2 | −6.9 | −6.5 | −4.0 |
| a*Rext30° | −1.8 | 0.4 | −0.5 | −0.5 |
| b*Rext30° | 2.1 | −5.1 | −0.4 | 0.7 |
| a*Rext45° | −2.0 | 0.6 | 0.9 | 2.5 |
| b*Rext45° | 1.1 | −4.4 | 1.1 | 0.9 |
| a*Rext60° | −2.0 | 0.0 | −1.1 | 1.9 |
| b*Rext60° | 0.1 | −3.1 | 1.8 | 1.6 |

Table 5 shows that the two examples EV2a and EV2b according to the second aspect of the invention have a light transmittance TL identical to that of counterexamples CEV2a and CEV2b and an energy transmission, TE, that is better (lower) than that of counterexamples CEV2a and CEV2b.

Table 5 shows that two examples EV2a and EV2b according to the second aspect of the invention allow a solar factor TTS gain, compared to counterexamples CEV2a and CEV2b. This gain illustrates the synergistic effect of the combination of the tungsten oxide-based absorbent layer with the two adjacent dielectric modules and with the second module which comprises one, two or three succession(s).

The selectivity obtained is high; it is equal to or greater than 1.3 in the laminated glazing configuration.

The exterior and interior reflections are further very low; they are less than 12%.

The last six rows of Table 5 show the stability of the color according to a* and b*, in external reflection, at 30°, 45° and 60° relative to the a* and b* values at 0° of the eighth and ninth rows.

A third series of examples of a substrate according to the first aspect of the invention are disclosed in table 6, which indicates the composition and the thickness expressed in nanometers of the various layers.

TABLE 6

| | | | CE3a | CE3b | CE3c | E3 |
|---|---|---|---|---|---|---|
| 1004e | S2 | SiZr27N | — | — | 2 | 74 |
| 1004d | | SiO₂ | — | — | 71 | 28 |
| 1004c | S1 | SiZr27N | — | — | 96 | 18 |
| 1004b | | SiO₂ | — | — | 58 | 53 |
| 1004a | | Si₃N₄ | — | 12 | — | 9 |
| 1003 | | CWO | — | 5 | — | 64 |
| 1002c | | Si₃N₄ | 18 | 5 | 32 | 5 |
| 1002b | | NbN | 6.0 | 5.6 | 7.1 | 4.0 |
| 1002a | | Si₃N₄ | 34 | 39 | 33 | 52 |
| 1000 | | glass | 6 mm | 6 mm | 6 mm | 6 mm |

The absorbent tungsten oxide (CWO) layer and the silicon nitride, Si₃N₄, silicon dioxide, SiO₂, and silicon-zirconium nitride, SiZr27N, layers are deposited like for the examples and counterexamples of the first series of examples of Tables 2 and 3.

Like for the first series of examples of Tables 2 and 3, all of the properties of this example and these counterexamples are disclosed in Table 7. The light transmittance of these examples and counter-examples is lower than previously; it is about 50%.

TABLE 7

| | CE3a | CE3b | CE3c | E3 |
|---|---|---|---|---|
| TL | 49.0 | 49.0 | 49.0 | 49.0 |
| TE | 46.6 | 45.7 | 42.4 | 29.9 |
| TST | 55.7 | 55.5 | 52.6 | 43.3 |
| SEL | 0.88 | 0.88 | 0.93 | 1.13 |
| a*T | −1.8 | −1.9 | −3.2 | −3.4 |
| b*T | −3.0 | −3.0 | 1.1 | −3.0 |
| Rext | 17.1 | 14.0 | 14.2 | 9.0 |
| a*Rext | −2.9 | −2.8 | 2.0 | −3.0 |
| b*Rext | −2.3 | −3.9 | −6.0 | −6.0 |
| Rint | 26.0 | 27.9 | 21.3 | 14.1 |
| a*Rint | −0.4 | −0.8 | 2.0 | −6.0 |
| b*Rint | 2.0 | 1.2 | 1.9 | −10.2 |
| a*Rext30° | −3.0 | −3.0 | 3.0 | 0.3 |
| b*Rext30° | −2.8 | −4.5 | −3.8 | −2.2 |
| a*Rext45° | −3.0 | −3.0 | 1.8 | 1.4 |
| b*Rext45° | −3.2 | −4.8 | −0.3 | 1.9 |
| a*Rext60° | −2.3 | −2.3 | −1.7 | −1.2 |
| b*Rext60° | −2.7 | −3.9 | 1.7 | 3.0 |

Table 7 shows that example E3 has a light transmission TL identical to that of counterexamples CE3a, CE3b and CE3c and an energy transmission, TE, that is better (lower) than that of counterexamples CE3a, CE3b and CE3c.

The selectivity obtained by example E3 is high; higher than that of counterexamples CE3a to CE3c.

Table 7 shows that the two examples EV30a and EV30b according to the second aspect of the invention allow a solar factor TTS gain, compared to counterexamples CE3a to CE3c. This gain illustrates the synergistic effect of the combination of the tungsten oxide-based absorbent layer with the two adjacent dielectric modules and with the second module which comprises one, two or three succession(s).

The exterior and interior reflections of example 3 are further very low; they are less than 12%.

The last six rows of Table 7 show the stability of the color according to a* and b*, in external reflection, at 30°, 45° and 60° relative to the a* and b* values at 0° of the eighth and ninth rows.

The examples according to the invention have reflection levels on the internal face and on the external face less than, or otherwise equivalent to less than, those of the counter-examples for comparable light transmission values. In other words, the invention also makes it possible to reduce light reflection, in particularly on the internal face, while preserving the same level of light transmission.

In transmission, the examples according to the invention have a lower color parameter b* than the counter-example.

In external face reflection, the examples according to the invention have a lower color parameter b*Rext than the counter-example.

In internal face reflection, the examples according to the invention have lower color parameters a*Rint and b*Rint than the counter-example.

1. A transparent substrate provided on one of its main surfaces with a stack of thin layers, said stack of layers consists of the following layers starting from the substrate:
a first dielectric module of one or several thin layers;
an absorbent tungsten oxide layer;
a second dielectric module of several thin layers;
wherein the tungsten oxide comprises at least one doping element selected from the chemical elements of group 1 according to the IUPAC nomenclature.

2. The substrate according to claim 1, wherein said second dielectric module comprises at least one succession of two layers with a low-index layer having a refractive index at 550 nm comprised between 1.50 and less than 1.90 and a high-index layer having a refractive index at 550 nm comprised between more than 2.10 and 2.70.

3. According to claim 2, wherein said second dielectric module comprises two successions of two layers, or even three successions of two layers, with, for each succession, a low-index layer and a high-index layer.

4. The substrate according to claim 2, wherein said low-index layer is chosen from a material based on silicon dioxide SiO₂ and said high-index layer is chosen from a material from a material based on zirconium silicon nitride-zirconium SiₓN_{y}Zr_{z}, or titanium dioxide TiO₂.

5. The substrate according to claim 1, wherein the absorbent tungsten oxide layer comprises the doping element or several doping elements in proportions such that a molar ratio of said element to tungsten or a sum of molar ratios of each element to tungsten is between 0.01 and 1.

6. The substrate according to claim 1, wherein the absorbent tungsten oxide layer comprises at least one doping element selected from hydrogen, lithium, sodium, potassium and cesium.

7. The substrate according to claim 6, wherein the absorbent tungsten oxide layer comprises cesium as a doping element, and a molar ratio of cesium to tungsten is between 0.01 and 1.

8. The substrate according to claim 1, wherein a thickness of the absorbent tungsten oxide layer is between 6 nm and 450 nm.

9. The substrate according to claim 1, wherein the first dielectric module and/or the second dielectric module comprises one or more nitride-based layers.

10. A single or double glazing comprising a transparent substrate according to claim 1.

11. A laminated glass comprising a first transparent substrate according to claim 1, a lamination interlayer and a second transparent substrate, such that the first transparent substrate and the second transparent substrate are in adhesive contact with the lamination interlayer and the stack of thin layers of the first transparent substrate is in contact with the lamination interlayer.

12. A method for manufacturing a transparent substrate according to claim 1, comprising depositing such that the absorbent tungsten oxide layer by a magnetron sputtering method using a tungsten oxide target doped using a chemical element chosen from the chemical elements of group 1 according to the IUPAC nomenclature.

13. The manufacturing method according to claim 12, wherein the absorbent tungsten oxide layer is deposited at a substrate temperature of less than 100° C.

14. The manufacturing method according to claim 12, wherein the absorbent tungsten oxide layer is deposited in a deposition atmosphere composed of 60% to 100% argon and 0% to 40% dioxygen.

15. The manufacturing method according to claim 12, wherein the absorbent tungsten oxide layer is deposited at a pressure of between 1 and 15 m Torr.

16. The substrate according to claim 2, wherein said low-index layer is closer to said absorbent tungsten oxide layer than said high-index layer.

17. The substrate according to claim 3, wherein said successions each being with said low-index layer of the succession closer to said absorbent tungsten oxide layer than said high-index layer of the succession.

18. The substrate according to claim 5, wherein the molar ratio of said element to tungsten or the sum of the molar ratios of each element to tungsten is between 0.01 and 0.6.

19. The substrate according to claim 7, wherein the molar ratio of cesium to tungsten is between 0.05 and 0.4.

20. The substrate according to claim 8, wherein the thickness of the absorbent tungsten oxide layer is between 20 nm and 250 nm.
